(19) United States
(12) Patent Application Publication
(10) Pub. No.: US 2005/0266649 A1
(43) Pub. Date: Dec. 1, 2005

(54) Electronic device manufacturing apparatus

(75) Inventors: Masahiko Niwayama, Kyoto (JP); Kenji Yoneda, Kyoto (JP); Kazuma Takahashi, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/097,140

(22) Filed: Apr. 4, 2005

(30) Foreign Application Priority Data
May 27, 2004 (JP) 2004-157139

(51) Int. Cl. H01L 21/00

(52) U.S. Cl. 438/303; 118/725; 438/60

(57) ABSTRACT

An electronic device manufacturing apparatus is provided with a support which includes a shelf for supporting a substrate, a sensor which obtains the position of the substrate and a position correcting mechanism which corrects the position of the substrate. Or alternatively, an electronic device manufacturing apparatus is provided with a support which includes a shelf for supporting a substrate and the shelf includes a substrate support plane which forms an angle of 22° or more to 90° or less with a horizontal plane.

### CROSS-REFERENCE TO RELATED APPLICATION

This non-provisional application claims priority under 35 U.S.C. § 119(a) on Patent Application No. 2004-157139 filed in Japan on May 27, 2004, the entire contents of which are hereby incorporated by reference.

### BACKGROUND OF THE INVENTION

(a) Field of the Invention

The present invention relates to an electronic device manufacturing apparatus. In particular, it relates to a semiconductor manufacturing apparatus which performs rapid thermal processing.

(b) Description of Related Art

In semiconductor manufacturing processes, highly accurate temperature control is often required during substrate processing. In particular, in rapid thermal processing (hereinafter abbreviated as RTP) which determines device characteristics, it is necessary to ensure temperature reproducibility and enhance temperature uniformity across the surface of a wafer.

For example, as described in Japanese Unexamined Patent Publication No. 2002-503884, importance has been placed on how to improve the temperature uniformity across the wafer surface in an apparatus which performs RTP.

FIG. 12 is a view illustrating a schematic configuration of a conventional RTP apparatus. In an RTP apparatus having no susceptor, in general, an edge ring is used in a process chamber to support a substrate by the periphery thereof. More specifically, as shown in FIG. 12, a semiconductor substrate 150 is placed on an edge ring 101 which is a substrate support arranged on the sidewall of a chamber 100. The edge ring 101 includes a shelf 102 for supporting the semiconductor substrate 150. The semiconductor substrate 150 is heated from above by a heater 103 provided at the upper part of the chamber 100. The heater 103 is divided into two or more regions so that the heating intensity of the heater 103 can be adjusted region by region. The temperature of the semiconductor substrate 150 (to be exact, the temperature of the rear surface of the substrate) is measured by a pyrometer 104 arranged at the bottom of the chamber 100. Though not shown, the edge ring 101 is generally provided with a rotating mechanism, and therefore it rotates together with the semiconductor substrate 150 during substrate processing.

FIG. 13A shows a planar configuration of the edge ring 101 including the shelf 102, while FIG. 13B shows a cross-sectional configuration of the shelf 102 viewed at any part of the edge ring 101 shown in FIG. 13A (e.g., a region circled with an alternate long and short dash line in FIG. 13A). The shelf 102 shown in FIG. 13B includes a horizontal substrate support plane 102a having a length W (length in the direction of the wafer diameter) of about 5 mm in general. The diameter (outer diameter) of a ring-shaped part, which serves as the substrate support plane 102a (inner diameter of the shelf 102), is 1 to 10 mm larger than the diameter of a wafer as the semiconductor substrate 150.

### SUMMARY OF THE INVENTION

When the edge ring 101 is used to support the semiconductor substrate 150, heat balance at the periphery of the semiconductor substrate 150 contacting the edge ring 101 varies from that at the other part of the semiconductor substrate 150 not contacting the edge ring 101. More specifically, in conventional thermal processing performed at about 1,000° C., in which temperature is raised by about 50° C./sec to reach a processing temperature and the processing temperature is maintained for about 10 seconds, temperature uniformity is obtained across the entire surface of the semiconductor substrate 150 by adjusting the intensities of the divided regions of the heater 103. However, if temperature is raised by 100° C. or higher/sec (i.e., the temperature is changed rapidly) to reach a processing temperature much higher than 1,000° C. as in spike RTA (rapid thermal annealing) which has been demanded in recent years (processing temperature T [° C.] is maintained for substantially 0 second and processing temperature not lower than (T−50) [° C.] is maintained for 2 seconds or less), it is getting difficult to ensure the temperature uniformity across the wafer surface by merely adjusting the intensities of the divided regions of the heater 103.

Under the above-described circumstances, an object of the present invention is to provide an electronic device manufacturing apparatus which allows thermal processing while excellent temperature uniformity is ensured across the wafer surface.

To achieve the object, the inventors of the present application have conducted various studies. The results are described below.

FIG. 14 is a graph of the measurement results of sheet resistance at the surface of the semiconductor substrate 150 which has been implanted with p- or n-type impurities and then subjected to RTP (spike RTA) using a conventional RTP apparatus. In FIG. 14, the lateral axis indicates locations on the wafer as the semiconductor substrate 150 (represented by the distance from the center point of the wafer (0) along the direction of the wafer diameter) and the longitudinal axis indicates normalized sheet resistance.

As shown in FIG. 14, through the spike RTA, the semiconductor substrate 150 shows significant variations in sheet resistance at the periphery thereof. This indicates that the temperature on the wafer surface has been greatly varied. Further, in spite that the semiconductor substrate 150 is rotated, the maximum and minimum sheet resistances co-exist on both ends of the wafer in the direction of the wafer diameter. Thus, the temperature uniformity across the wafer surface cannot be fully ensured by merely adjusting the intensities of the divided regions of the heater 103. This results from a great difference in heat balance among parts of the periphery of the semiconductor substrate 150 due to a difference in area of contact between the parts of the periphery of the semiconductor substrate 150 and the edge ring 101. More specifically, when the center of the semiconductor substrate 150 is not aligned with the center of the edge ring 101, the parts of the periphery of the semiconductor substrate 150 vary in area of contact with the edge ring 101. This brings about temperature nonuniformity across the wafer surface.

Further, heat balance at the periphery of the semiconductor substrate 150 contacting the edge ring 101 is greatly different from that at the other part of the semiconductor substrate 150 not contacting the edge ring 101. The degree of temperature nonuniformity increases with an increase in area of contact between the periphery of the semiconductor substrate 150 and the edge ring 101.

As described above, it has been found that the temperature uniformity across the surface of the semiconductor substrate 150 greatly depends on both the positional relationship and the area of contact between the semiconductor substrate 150 and the edge ring 101.

Based on the above finding, the present invention has been achieved. More specifically, a first electronic device manufacturing apparatus of the present invention comprises a support which includes a shelf for supporting a substrate, a sensor which obtains the position of the substrate and a position correcting mechanism which corrects the position of the substrate.

Further, a method for manufacturing the first electronic device manufacturing apparatus of the present invention comprises the steps of: placing the substrate on the shelf; obtaining the position of the substrate placed on the shelf using the sensor; and correcting the position of the substrate using the position correcting mechanism based on the position of the substrate obtained by the sensor.

According to the first electronic device manufacturing apparatus and the manufacturing method, the sensor obtains the position of the substrate placed on the shelf of the support, and then the position correcting mechanism corrects the position of the substrate based on the obtained results. This allows correcting the position of the substrate such that the center of the substrate is aligned with the center of the shelf. Therefore, every part of the periphery of the substrate contacts the shelf with the same area, i.e., the state of contact of the periphery of the semiconductor substrate with the shelf becomes the same in every part thereof. As a result, heat balance at the periphery of the substrate contacting the shelf is brought into better balance with that at the other part of the substrate not contacting the shelf. Thus, temperature uniformity improves across the substrate surface during thermal processing, specifically RTP.

A second electronic device manufacturing apparatus comprises a support which includes a shelf for supporting a substrate, wherein the shelf includes a substrate support plane which forms an angle of 22° or more to less than 23° with a horizontal plane.

According to the second electronic device manufacturing apparatus, the shelf for supporting the substrate includes the substrate support plane which forms an angle of 22° or more to less than 23° with a horizontal plane. Even if the center of the substrate is misaligned with the center of the shelf when the substrate is placed on the shelf, the substrate slides along the substrate support plane of the shelf under its own weight, whereby the centers of the substrate and the shelf are aligned in the end. Therefore, every part of the periphery of the substrate contacts the shelf with the same area, i.e., the state of contact of the periphery of the semiconductor substrate with the shelf becomes the same in every part thereof. As a result, heat balance at the periphery of the substrate contacting the shelf is brought into better balance with that at the other part of the substrate not contacting the shelf. Thus, temperature uniformity improves across the substrate surface during thermal processing, specifically RTP. Where the centers of the substrate and the shelf are aligned, the substrate support plane is brought into contact with a beveled face of the substrate whose length is as small as about 0.5 mm (length in the direction of the wafer diameter). This reduces the area of contact between the periphery of the substrate and the shelf. As a result, heat balance at the periphery of the substrate contacting the shelf becomes less different from that at the other part of the substrate not contacting the shelf. Thus, temperature uniformity further improves across the substrate surface during RTP.

A third electronic device manufacturing device of the present invention comprises a support which includes a shelf for supporting a substrate, wherein the shelf includes a substrate support plane which forms an angle of 23° or more to less than 90° with a horizontal plane.

According to the third electronic device manufacturing device of the present invention, the shelf supporting the substrate includes the substrate support plane which forms an angle of 23° or more to less than 90° with a horizontal plane. Even if the center of the substrate is misaligned with the center of the shelf when the substrate is placed on the shelf, the substrate slides along the substrate support plane of the shelf under its own weight, whereby the centers of the substrate and the shelf are aligned in the end. Therefore, every part of the periphery of the substrate contacts the shelf with the same area, i.e., the state of contact of the periphery of the semiconductor substrate with the shelf becomes the same in every part thereof. As a result, heat balance at the periphery of the substrate contacting the shelf is brought into better balance with that at the other part of the substrate not contacting the shelf. Thus, temperature uniformity improves across the substrate surface during thermal processing, specifically RTP. Where the centers of the substrate and the shelf are aligned, the substrate support plane is brought into contact with an edge of the substrate at which a beveled face of the substrate meets an end face of the substrate. This reduces the area of contact between the periphery of the substrate and the shelf to a great extent. As a result, heat balance at the periphery of the substrate contacting the shelf becomes less different from that at the other part of the substrate not contacting the shelf. Thus, temperature uniformity further improves across the substrate surface during RTP.

A fourth electronic device manufacturing apparatus of the present invention comprises a support which includes a shelf for supporting a substrate, wherein the shelf includes a substrate support plane which forms an angle of 90° with a horizontal plane.

According to the fourth electronic device manufacturing apparatus, the shelf supporting the substrate includes the substrate support plane which forms an angle of 90° with a horizontal plane. That is, the substrate is supported in such a state that an end face thereof contacts the substrate support plane of the shelf, whereby the centers of the substrate and the shelf are aligned. Therefore, every part of the periphery of the substrate contacts the shelf with the same area, i.e., the state of contact of the periphery of the semiconductor substrate with the shelf becomes the same in every part thereof. As a result, heat balance at the periphery of the substrate contacting the shelf is brought into better balance with that at the other part of the substrate not contacting the shelf. Thus, temperature uniformity improves across the substrate surface during thermal processing, specifically RTP. Where the centers of the substrate and the shelf are aligned, the substrate support plane is brought into contact with the end face of the substrate whose length is as small as about 0.5 mm or less. This reduces the area of contact between the periphery of the substrate and the shelf. As a result, heat balance at the periphery of the substrate contacting the shelf becomes less different from that at the other part of the substrate not contacting the shelf. Thus, temperature uniformity further improves across the substrate surface during RTP.

As described above, the present invention relates to an electronic device manufacturing apparatus which performs thermal processing. The present invention is highly useful for its effect of giving excellent temperature uniformity across the wafer surface when applied to RTP.

### BRIEF DESCRIPTION OF THE DRAWINGS

FIG. 1 is a sectional view illustrating a schematic configuration of an electronic device manufacturing apparatus according to Embodiment 1 of the present invention.

FIG. 2 is a view illustrating a feature of the electronic device manufacturing apparatus according to Embodiment 1 of the present invention.

FIG. 3 is a view illustrating a transfer arm as a substrate position correcting mechanism provided outside a process chamber of the electronic device manufacturing apparatus according to Embodiment 1 of the present invention.

FIG. 4A is a view illustrating a planar configuration of an edge ring including a shelf of the electronic device manufacturing apparatus according to Embodiment 1 of the present invention and FIG. 4B is a view illustrating a cross-sectional configuration of the shelf viewed at any part of the edge ring shown in FIG. 4A.

FIG. 5 is a graph of the measurement results of sheet resistance at the surface of a semiconductor substrate which has been implanted with p- or n-type impurities and then subjected to spike RTA using the electronic device manufacturing apparatus of Embodiment 1 of the present invention.

FIG. 6A is a view illustrating a planar configuration of an edge ring including a shelf of an electronic device manufacturing apparatus according to Embodiment 2 of the present invention and FIG. 6B is a view illustrating a cross-sectional configuration of the shelf viewed at any part of the edge ring shown in FIG. 6A.

FIG. 7A is a view illustrating a cross-sectional configuration of the periphery of a semiconductor substrate to be placed on the shelf of the edge ring of the electronic device manufacturing apparatus according to Embodiment 2 of the present invention and FIG. 7B is a view illustrating the semiconductor substrate placed on the shelf of the edge ring of the electronic device manufacturing apparatus according to Embodiment 2 of the present invention.

FIG. 8A is a view illustrating a planar configuration of an edge ring including a shelf of an electronic device manufacturing apparatus according to Embodiment 3 of the present invention and FIG. 8B is a view illustrating a cross-sectional configuration of the shelf viewed at any part of the edge ring shown in FIG. 8A.

FIG. 9 is a view illustrating a semiconductor substrate placed on the shelf of the edge ring of the electronic device manufacturing apparatus according to Embodiment 3 of the present invention.

FIG. 10A is a view illustrating a planar configuration of an edge ring including a shelf of an electronic device manufacturing apparatus according to Embodiment 4 of the present invention and FIG. 10B is a view illustrating a cross-sectional configuration of the shelf viewed at any part of the edge ring shown in FIG. 10A.

FIG. 11 is a view illustrating a semiconductor substrate placed on the shelf of the edge ring of the electronic device manufacturing apparatus according to Embodiment 4 of the present invention.

FIG. 12 is a view illustrating a schematic configuration of a conventional RTP apparatus.

FIG. 13A is a view illustrating a planar configuration of an edge ring including a shelf of the conventional RTP apparatus and FIG. 13B is a view illustrating a cross-sectional configuration of the shelf viewed at any part of the edge ring shown in FIG. 13A.

FIG. 14 is a graph of the measurement results of sheet resistance at the surface of a semiconductor substrate which has been implanted with p- or n-type impurities and then subjected to spike RTA using the conventional RTP apparatus.

### DETAILED DESCRIPTION OF THE INVENTION

### Embodiment 1

Hereinafter, with reference to the drawings, an explanation is given of an electronic device manufacturing apparatus and a manufacturing method according to Embodiment 1 of the present invention. In this embodiment, an RTP apparatus is taken as an example.

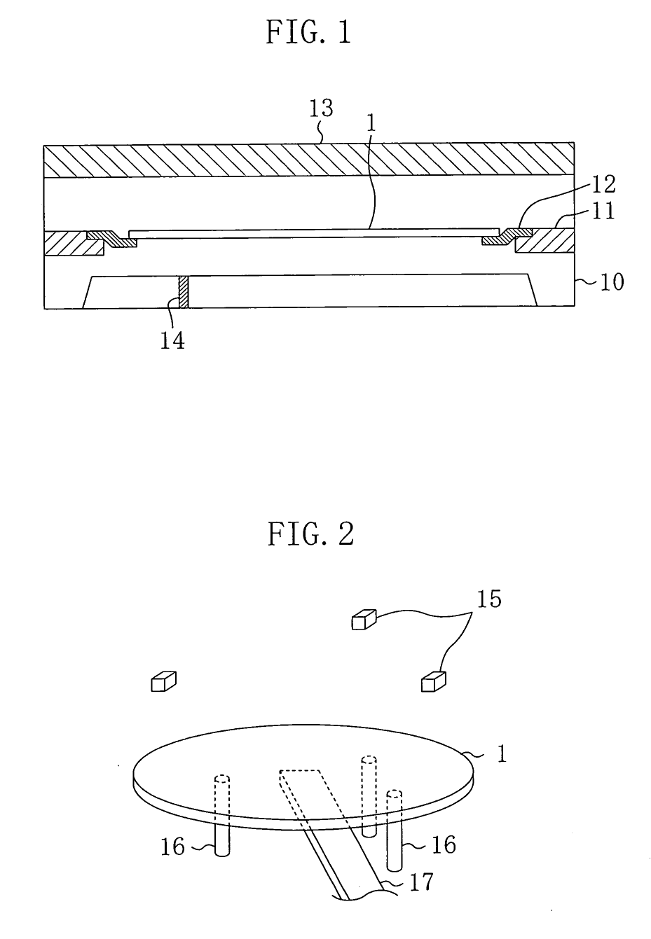

FIG. 1 is a sectional view illustrating a schematic configuration of an electronic device manufacturing apparatus of Embodiment 1. As shown in FIG. 1, an edge ring 11 for supporting a semiconductor substrate 1 is provided on the sidewall of a chamber 10. The edge ring 11 includes a shelf 12 for supporting the semiconductor substrate 1. A heater 13 is provided at the upper part of the chamber 10 so that the semiconductor substrate 1 is heated from above. The heater 13 is divided into two or more regions so that the heating intensity of the heater 13 can be adjusted region by region. Further, a pyrometer 14 is provided at the bottom of the chamber 10 to measure the temperature of the semiconductor substrate 1 (to be exact, the temperature of the rear surface of the semiconductor substrate). Thus, in the apparatus shown in FIG. 1, thermal processing of the semiconductor substrate 1 is carried out by adjusting the intensity of the heater 13 region by region in accordance with the substrate temperature measured by the pyrometer 14. Though not shown, the edge ring 11 is provided with a rotating mechanism, and therefore it rotates together with the semiconductor substrate 1 during substrate processing.

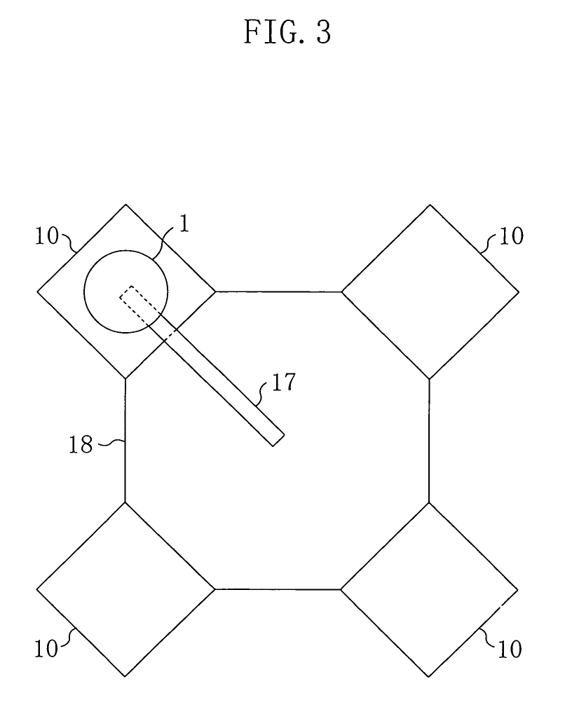

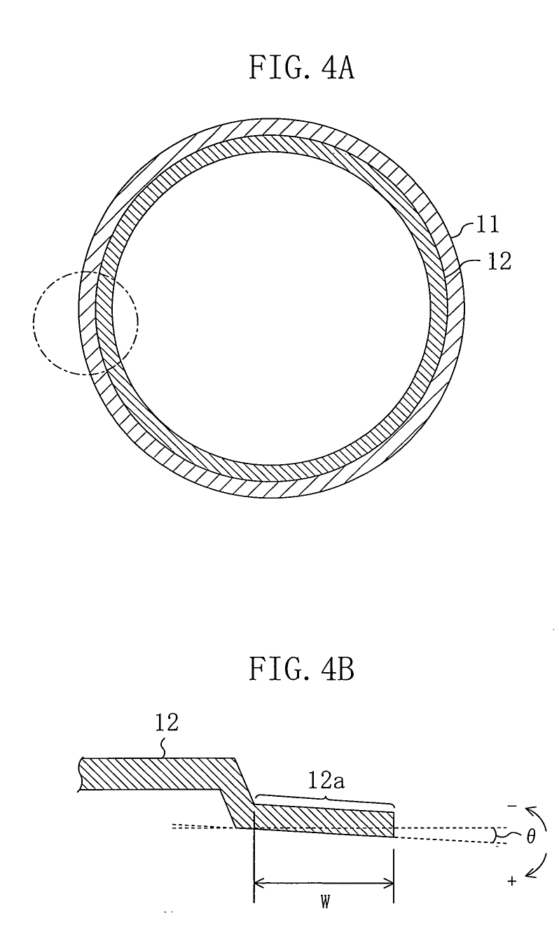

FIG. 2 shows a feature of the present embodiment in the chamber 10. As shown in FIG. 2, the chamber 10 includes one or more sensors 15 for obtaining the position of the semiconductor substrate 1 placed on the edge ring 11. It goes without saying that where to arrange the sensors 15 is not particularly limited. The chamber 10 further includes three support pins 16, for example, for supporting a wafer as the semiconductor substrate 1 placed on the edge ring 11. The position of the semiconductor substrate 1 placed on the edge ring 11 is corrected by a substrate position correcting mechanism, i.e., the support pins 16 or a transfer arm 17 (a robot arm for transferring the wafer). As shown in FIG. 3, the transfer arm 17 is provided for a transfer chamber 18 including two or more chambers 10 shown in FIG. 1.

Hereinafter, an explanation is given of a method for correcting the substrate position using the substrate position correcting mechanism described above. When the semiconductor substrate 1 is transferred into the chamber 10 and placed on the edge ring 11, the sensors 15 obtain the position of the semiconductor substrate 1, to be exact, the interval between the center of the semiconductor substrate 1 and the center of the shelf 12 (i.e., the center of the edge ring 11: the same is applied below). If the obtained interval is more than 0.3 mm, the position of the semiconductor substrate 1 is corrected using the support pins 16 or the transfer arm 17 to reduce the interval to 0.3 mm or less. Preferably, the interval is reduced to 0.1 mm or less by the correction.

FIG. 4A shows a planar configuration of the edge ring 11 including the shelf 12 according to the present embodiment, while FIG. 4B shows a cross-sectional configuration of the shelf 12 viewed at any part of the edge ring 11 shown in FIG. 4A (e.g., a region circled with an alternate long and short dash line in FIG. 4A). As shown in FIG. 4B, the shelf 12 includes a substrate support plane 12a which forms an angle (θ) of 2° with a horizontal plane and has a length W of 3 mm (horizontal length along the direction of the wafer diameter).

In the present invention, as shown in FIG. 4B, the angle formed by the horizontal plane and the substrate support plane 12a whose distal end is positioned lower than the horizontal plane is regarded as a positive angle, while the angle formed by the horizontal plane and the substrate support plane 12a whose distal end is positioned upper than the horizontal plane is regarded as a negative angle.

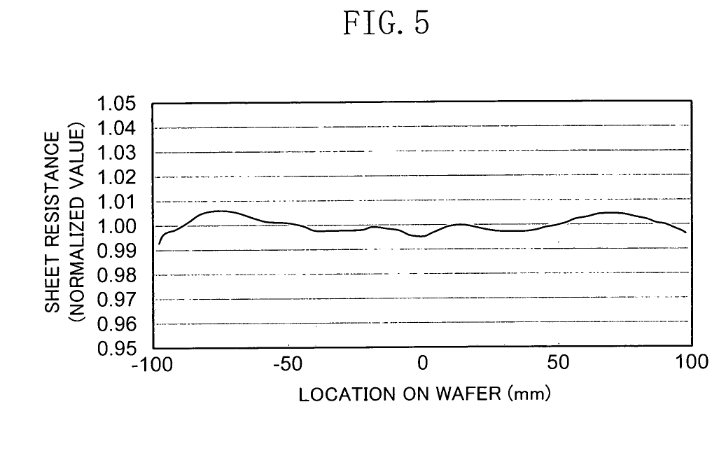

FIG. 5 is a graph of the measurement results of sheet resistance at the surface of the semiconductor substrate 1 which has been implanted with p- or n-type impurities and then subjected to RTP (spike RTA) using the manufacturing apparatus of the present embodiment. In FIG. 5, the lateral axis indicates locations on the wafer as the semiconductor substrate 1 (represented by the distance from the wafer center (0) along the direction of the wafer diameter) and the longitudinal axis indicates normalized sheet resistance.

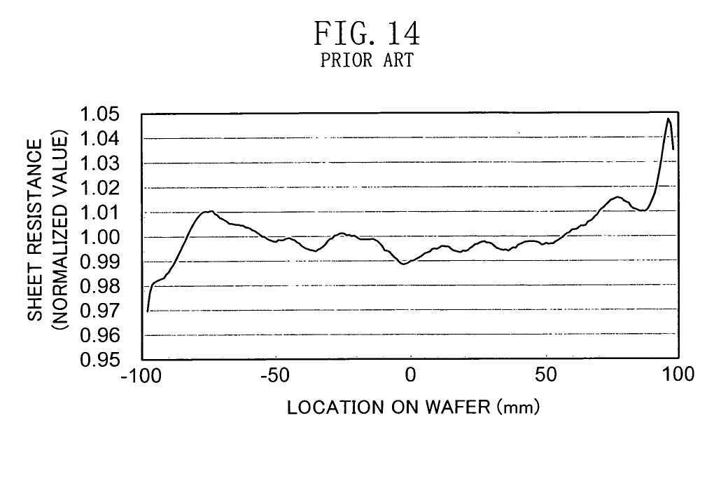

As shown in FIG. 5, the measured sheet resistance has improved in uniformity as compared with the sheet resistance measured at the wafer periphery after spike RTA performed with the conventional manufacturing apparatus (see FIG. 14). At almost every part of the surface of the wafer (semiconductor substrate 1), the sheet resistance is symmetric to that at the wafer center. To be more specific, variations in sheet resistance are restricted within 3° C. on temperature conversion.

That is, according to Embodiment 1, the sensors 15 obtain the position of the semiconductor substrate 1 placed on the shelf 12 of the edge ring 11, and then the position correcting mechanism (e.g., the support pins 16 or the transfer arm 17) corrects the position of the semiconductor substrate 1 based on the obtained results. Since the semiconductor substrate 1 is positioned properly such that the center thereof is aligned with the center of the shelf 12, every part of the periphery of semiconductor substrate 1 contacts the shelf 12 with the same contact area. That is, the state of contact of the semiconductor substrate 1 with the shelf 12 becomes the same in every part thereof. Therefore, heat balance at the periphery of the semiconductor substrate 1 contacting the shelf 12 is brought into better balance with that at the other part of the semiconductor substrate 1 not contacting the shelf 12. As a result, temperature uniformity improves across the substrate surface during thermal processing, specifically RTP.

Further, according to Embodiment 1, the length W of the substrate support plane 12a of the shelf 12 is at most about 3 mm, and therefore the area of contact between the periphery of the semiconductor substrate 1 and the shelf 12 is reduced. As a result, heat balance at the periphery of the semiconductor substrate 1 contacting the shelf 12 becomes less different from that at the other part of the semiconductor substrate 1 not contacting the shelf 12. Thus, the temperature uniformity further improves across the substrate surface during RTP.

In Embodiment 1, the length W of the substrate support plane 12a is set to 3 mm. However, the same effect is obtained as in the present embodiment even if the length W is 3 mm or less.

In Embodiment 1, the angle θ formed by the substrate support plane 12a of the shelf 12 and the horizontal plane is set to 2°. However, the same effect is obtained as in the present embodiment as long as the angle θ is in the range of −5° or more to 22° or less.

In Embodiment 1, the substrate position correcting mechanism may be provided inside the process chamber. Or alternatively, a robot arm of a transfer system provided outside the process chamber may be used as the substrate position correcting mechanism. In either case, the same effect is obtained as in the present embodiment.

### Embodiment 2

Hereinafter, with reference to the drawings, an explanation is given of an electronic device manufacturing apparatus according to Embodiment 2 of the present invention. In this embodiment, an RTP apparatus is taken as an example. A feature of the present embodiment lies in an edge ring 11 (especially a shelf 12 thereof) in an electronic device manufacturing apparatus as shown in FIG. 1 (an RTP apparatus, to be exact). Except this feature, the manufacturing apparatus of Embodiment 2 is configured in the same manner as that of Embodiment 1.

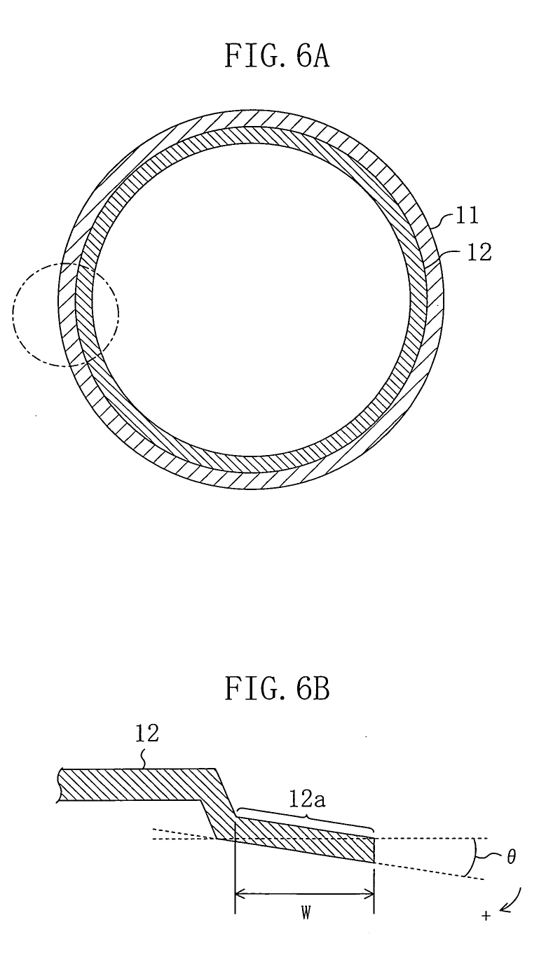

FIG. 6A shows a planar configuration of the edge ring 11 including the shelf 12 according to the present embodiment, while FIG. 6B shows a cross-sectional configuration of the shelf 12 viewed at any part of the edge ring 11 shown in FIG. 6A (e.g., a region circled with an alternate long and short dash line in FIG. 6A). As shown in FIG. 6B, the shelf 12 includes a substrate support plane 12a which forms an angle (θ) of 22° with a horizontal plane and has a length W of 4 mm (horizontal length along the direction of the wafer diameter).

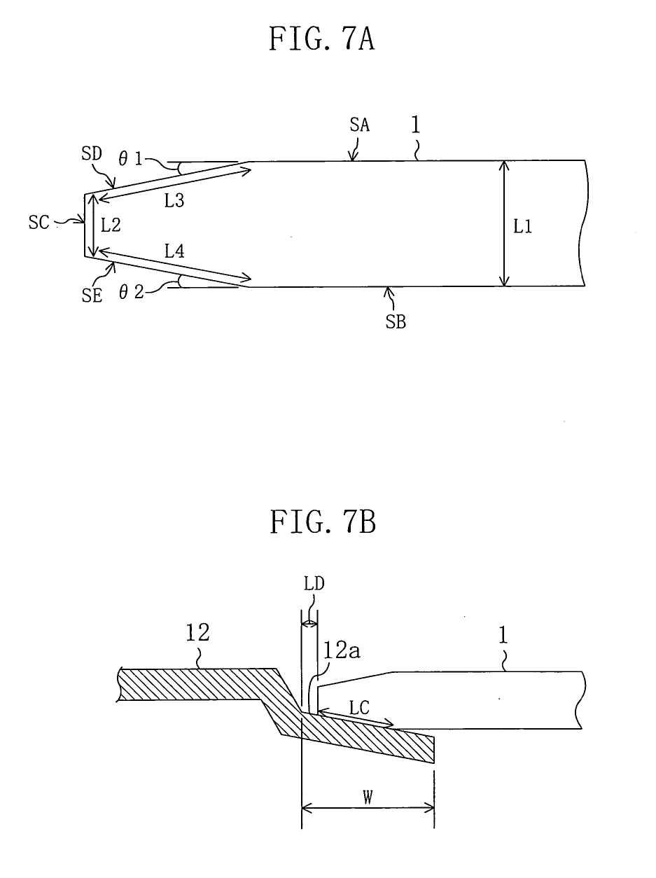

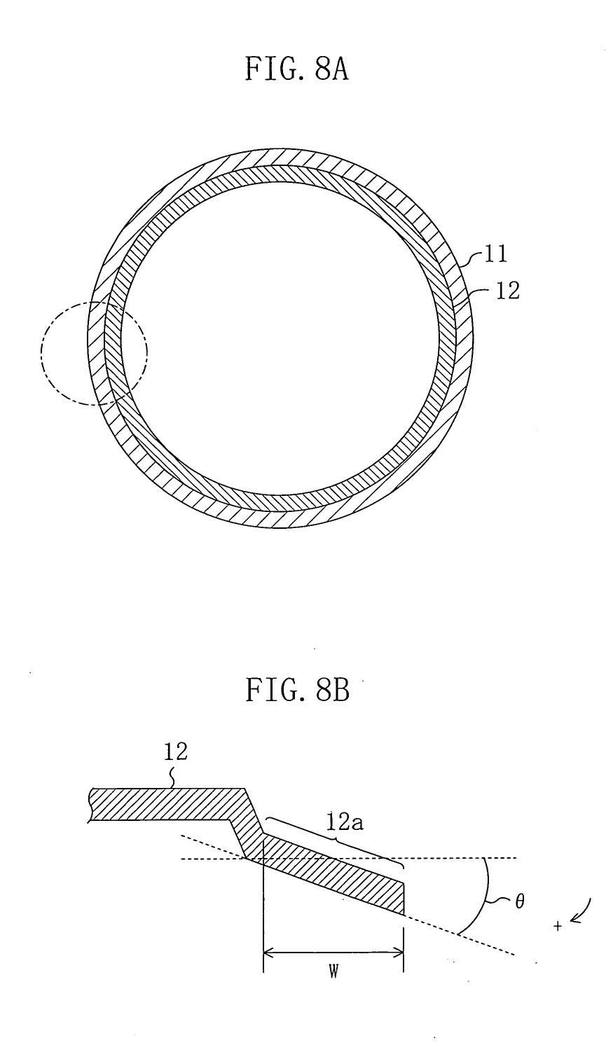

FIG. 7A shows a cross-sectional configuration of the periphery of the semiconductor substrate 1 to be placed on the shelf 12 of the edge ring 11 of the present embodiment, while FIG. 7B shows the semiconductor substrate 1 placed on the shelf 12 of the edge ring 11 of the present embodiment.

As shown in FIG. 7A, the front surface (upper surface) SA and the rear surface (lower surface) SB of the semiconductor substrate 1 are given with an upper beveled face SD and a lower beveled face SE which are in contact with an end face (peripheral face) SC of the semiconductor substrate 1, respectively. An angle θ1 formed by the upper surface SA and the upper beveled face SD and an angle θ2 formed by the lower surface SB and the lower beveled face SE are about 22° to 23°, respectively. Further, as shown in FIG. 7A, the semiconductor substrate 1 has a thickness L1 (distance from the upper surface SA to the lower surface SB) of about 770 μm, for example. The end face SC has a length L2 of about 385 μm and the upper beveled face SD and the lower beveled face SE have lengths L3 and L4 of about 500 μm, respectively. Further, as shown in FIG. 7B, a ring-shaped part, which serves as the substrate support plane 12a of the shelf 12 of the edge ring 11, has a diameter (outer diameter: hereinafter referred to as an inner diameter of the shelf 12) which is 1 mm larger than the diameter of a wafer as the semiconductor substrate 1. That is, where the center of the edge ring 11 is aligned with the center of the semiconductor substrate 1, a distance LD shown in FIG. 7B is about 500 μm.

With use of the thus-configured edge ring 11, the substrate support plane 12a of the shelf 12 contacts the lower beveled face SE of the semiconductor substrate 1 as shown in FIG. 7B. At this time, part of the periphery of the semiconductor substrate 1 contacting the shelf 12 has a length LC of about 500 μm, which is equal to the length L4 of the lower beveled face SE (see FIG. 7A).

According to Embodiment 2, the shelf 12 supporting the semiconductor substrate 1 includes the substrate support plane 12a which forms an angle of 22° or more to less than 23° with the horizontal plane. Therefore, even if the center of the semiconductor substrate 1 is misaligned with the center of the shelf 12 (the center of the edge ring 11) when the semiconductor substrate 1 is placed on the shelf 12, the semiconductor substrate 1 slides along the substrate support plane 12a of the shelf 12 under its own weight, whereby the center of the semiconductor substrate 1 is aligned with the center of the shelf 12. At this time, the interval between the center point of the shelf 12 and the center point of the semiconductor substrate 1 is reduced to 0.3 mm or less, or possibly 0.1 mm or less. As a result, every part of the periphery of semiconductor substrate 1 contacts the shelf 12 with the same contact area. That is, the state of contact of the semiconductor substrate 1 with the shelf 12 becomes the same in every part thereof. Therefore, heat balance at the periphery of the semiconductor substrate 1 contacting the shelf 12 is brought into better balance with that at the other part of the semiconductor substrate 1 not contacting the shelf 12. As a result, temperature uniformity improves across the substrate surface during thermal processing, specifically RTP. Where the center of the semiconductor substrate 1 is aligned with the center of the shelf 12, the substrate support plane 12a is brought into contact with the lower beveled face SE of the semiconductor substrate 1 whose length is as small as about 1 mm (length in the direction of the wafer diameter). This reduces the area of contact between every part of the periphery of the semiconductor substrate 1 and the shelf 12. As a result, heat balance at the periphery of the semiconductor substrate 1 contacting the shelf 12 becomes less different from that at the other part of the semiconductor substrate 1 not contacting the shelf 12. Thus, temperature uniformity further improves across the substrate surface during RTP.

With use of the edge ring 11 of the present embodiment, the shelf 12 of the edge ring 11 contacts the semiconductor substrate 1 by 1 mm or less and every part of the periphery of semiconductor substrate 1 contacts the shelf 12 with the same contact area. Thus, the above-described significant effect is obtained.

In Embodiment 2, the angle θ formed by the substrate support plate 12a of the shelf 12 and the horizontal plane is 22°. However, the same effect is obtained as in the present embodiment even if the angle θ is in the range of 22° or more to less than 23°.

In Embodiment 2, the inner diameter of the shelf 12 of the edge ring 11 is made 1 mm larger than the diameter of the semiconductor substrate 1. However, the same effect is obtained as in the present embodiment as long as the inner diameter of the shelf 12 is larger than the diameter of the semiconductor substrate 1.

In Embodiment 2, the length W of the substrate support plate 12a is 4 mm. However, even if the length W is 2 mm or more, the same effect is obtained as in the present embodiment, i.e., the semiconductor substrate 1 slides along the substrate support plane 12a under its own weight such that the center of the semiconductor substrate 1 is aligned with the center of the shelf 12.

### Embodiment 3

Hereinafter, with reference to the drawings, an explanation is given of an electronic device manufacturing apparatus according to Embodiment 3 of the present invention. In this embodiment, an RTP apparatus is taken as an example. A feature of the present embodiment lies in an edge ring 11 (especially a shelf 12 thereof) of an electronic device manufacturing apparatus as shown in FIG. 1 (an RTP apparatus, to be exact). Except this feature, the manufacturing apparatus of Embodiment 3 is configured in the same manner as that of Embodiment 1.

FIG. 8A shows a planar configuration of the edge ring 11 including the shelf 12 according to the present embodiment, while FIG. 8B shows a cross-sectional configuration of the shelf 12 viewed at any part of the edge ring 11 shown in FIG. 8A (e.g., a region circled with an alternate long and short dash line in FIG. 8A). As shown in FIG. 8B, the shelf 12 includes a substrate support plane 12a which forms an angle (θ) of 45° with a horizontal plane and has a length W of 4 mm (horizontal length along the direction of the wafer diameter).

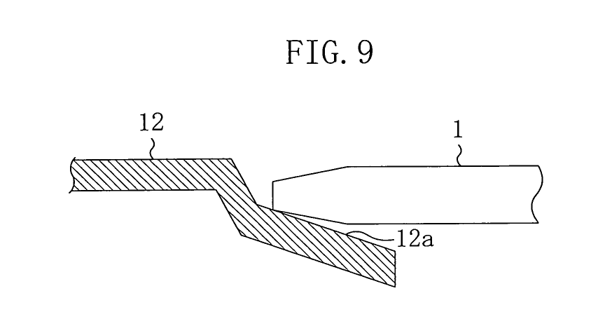

FIG. 9 shows a semiconductor substrate 1 placed on the shelf 12 of the edge ring 11. As shown in FIG. 9, a ring-shaped part, which serves as the substrate support plane 12a of the shelf 12 of the edge ring 11, has a larger diameter (outer diameter: hereinafter referred to as the inner diameter of the shelf 12) than a wafer as the semiconductor substrate 1. More specifically, the inner diameter of the shelf 12 is 1 mm larger than the diameter of the semiconductor substrate 1.

With use of the thus-configured edge ring 11, as shown in FIG. 9, the substrate support plane 12a of the shelf 12 contacts the semiconductor substrate 1 at an edge of the semiconductor substrate 1 at which the lower beveled face SE meets the end face SC (see FIG. 7A).

According to Embodiment 3, the shelf 12 supporting the semiconductor substrate 1 has the substrate support plane 12a which forms an angle of 45° with the horizontal plane. Therefore, even if the center of the semiconductor substrate 1 is misaligned with the center of the shelf 12 (the center of the edge ring 11) when the semiconductor substrate 1 is placed on the shelf 12, the semiconductor substrate 1 slides along the substrate support plane 12a of the shelf 12 under its own weight, whereby the center of the semiconductor substrate 1 is aligned with the center of the shelf 12. At this time, the interval between the center point of the shelf 12 and the center point of the semiconductor substrate 1 is reduced to 0.3 mm or less, or possibly 0.1 mm or less. As a result, every part of the periphery of semiconductor substrate 1 contacts the shelf 12 with the same contact area. That is, the state of contact of the semiconductor substrate 1 with the shelf 12 becomes the same in every part thereof. Therefore, heat balance at the periphery of the semiconductor substrate 1 contacting the shelf 12 is brought into better balance with that at the other part of the semiconductor substrate 1 not contacting the shelf 12. As a result, temperature uniformity improves across the substrate surface during thermal processing, specifically RTP. Where the center of the semiconductor substrate 1 is aligned with the center of the shelf 12, the substrate support plane 12a is brought into contact with the edge of the semiconductor substrate 1 at which the lower beveled face SE meets the end face SC. This reduces the area of contact between every part of the periphery of the semiconductor substrate 1 and the shelf 12. As a result, heat balance at the periphery of the semiconductor substrate 1 contacting the shelf 12 becomes less different from that at the other part of the semiconductor substrate 1 not contacting the shelf 12. Thus, temperature uniformity further improves across the substrate surface during RTP.

With use of the edge ring 11 of the present embodiment, the shelf 12 of the edge ring 11 and the semiconductor substrate 1 contact each other such that the contacting part is substantially in the form of a line and the state of contact of the semiconductor substrate 1 with the shelf 12 becomes the same in every part thereof. Thus, the above-described significant effect is obtained.

In Embodiment 3, the angle θ formed by the substrate support plane 12a of the shelf 12 and the horizontal plane is 45°. However, the same effect is obtained as in the present embodiment even if the angle θ is in the range of 23° or more to less than 90°.

In Embodiment 3, the inner diameter of the shelf 12 of the edge ring 11 is 1 mm larger than the diameter of the semiconductor substrate 1. However, the same effect is obtained as in the present embodiment as long as the inner diameter of the shelf 12 is larger than the diameter of the semiconductor substrate 1.

In Embodiment 3, the length W of the substrate support plane 12a is 4 mm. However, even if the length W is 2 mm or more, the same effect is obtained as in the present embodiment, i.e., the semiconductor substrate 1 slides along the substrate support plane 12a under its own weight such that the center of the semiconductor substrate 1 is aligned with the center of the shelf 12.

### Embodiment 4

Hereinafter, with reference to the drawings, an explanation is given of an electronic device manufacturing apparatus according to Embodiment 4 of the present invention. In this embodiment, an RTP apparatus is taken as an example. A feature of the present embodiment lies in an edge ring 11 (especially a shelf 12 thereof) of an electronic device manufacturing apparatus as shown in FIG. 1 (an RTP apparatus, to be exact). Except this feature, the manufacturing apparatus of Embodiment 4 is configured in the same manner as that of Embodiment 1.

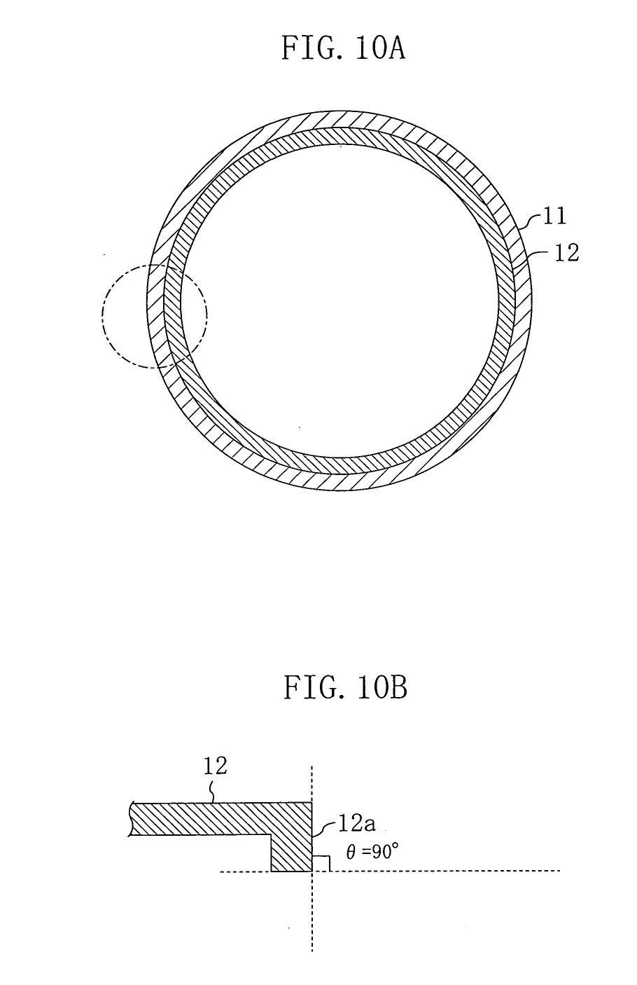

FIG. 10A shows a planar configuration of the edge ring 11 including the shelf 12 according to the present embodiment, while FIG. 10B shows a cross-sectional configuration of the shelf 12 viewed at any part of the edge ring 11 shown in FIG. 10A (e.g., a region circled with an alternate long and short dash line in FIG. 10A). As shown in FIG. 10B, the shelf 12 includes a substrate support plane 12a which forms an angle (θ) of 90° with a horizontal plane.

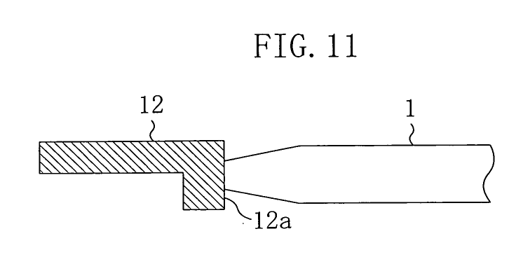

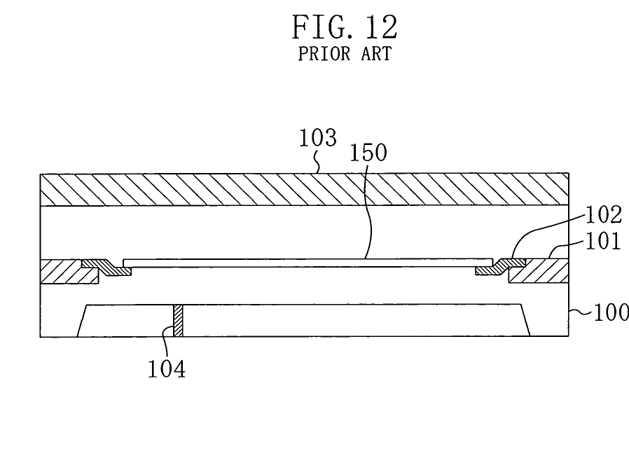

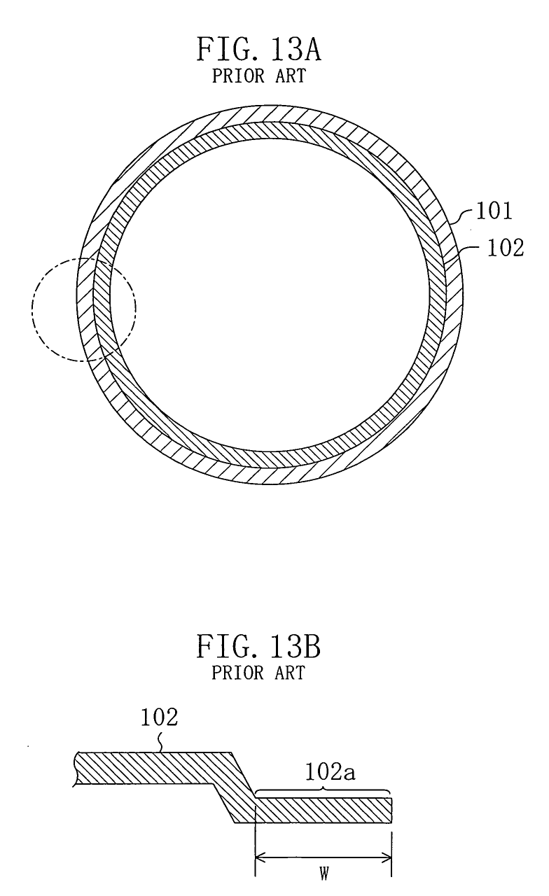

FIG. 11 shows the semiconductor substrate 1 supported by the shelf 12 of the edge ring 11 of the present embodiment. As shown in FIG. 11, the inner diameter of the shelf 12 of the edge ring 11 is the same as the diameter of a wafer as the semiconductor substrate 1.

With use of the thus-configured edge ring 11, as shown in FIG. 11, the substrate support plane 12a of the shelf 12 contacts the end face SC (see FIG. 7A) of the semiconductor substrate 11. At this time, part of the periphery of the semiconductor substrate 1 contacting the shelf 12 has a length of about 400 μm, which is the same as the length L3 of the end face SC (see FIG. 7A).

In Embodiment 4, the shelf 12 supporting the semiconductor substrate 1 includes the substrate support plane 12a which forms an angle of 90° with the horizontal plane. That is, the semiconductor substrate 1 is supported in such a state that the end face SC thereof contacts the substrate support plane 12a of the shelf 12. Thus, the center of the semiconductor substrate 1 is aligned with the center of the shelf 12. At this time, the interval between the center point of the semiconductor substrate 1 and the center point of the shelf 12 is reduced to 0.3 mm or less, or possibly 0.1 mm or less. As a result, every part of the periphery of semiconductor substrate 1 contacts the shelf 12 with the same contact area. That is, the state of contact of the semiconductor substrate 1 with the shelf 12 becomes the same in every part thereof. Therefore, heat balance at the periphery of the semiconductor substrate 1 contacting the shelf 12 is brought into better balance with that at the other part of the semiconductor substrate 1 not contacting the shelf 12. As a result, temperature uniformity improves across the substrate surface during thermal processing, specifically RTP. Where the center of the semiconductor substrate 1 is aligned with the center of the shelf 12, the substrate support plane 12a is brought into contact with the end face SC of the semiconductor substrate 1 which is as small as about 1 mm in length (length along the direction vertical to the wafer surface). This reduces the area of contact between every part of the periphery of the semiconductor substrate 1 and the shelf 12. As a result, the heat balance at the periphery of the semiconductor substrate 1 contacting the shelf 12 becomes less different from that at the other part of the semiconductor substrate not contacting the shelf 12. Thus, temperature uniformity further improves across the substrate surface during RTP.

With use of the edge ring 11 of the present embodiment, part of the semiconductor substrate 1 contacting the shelf 12 of the edge ring 11 substantially has a length of 1 mm or less and every part of the periphery of semiconductor substrate 1 contacts the shelf 12 with the same contact area. Therefore, the above-described significant effect is obtained.

1. An electronic device manufacturing apparatus comprising:
a support which includes a shelf for supporting a substrate;
a sensor which obtains the position of the substrate; and
a position correcting mechanism which corrects the position of the substrate.

2. An electronic device manufacturing apparatus according to claim 1, wherein
the shelf includes a substrate support plane which forms an angle of −5° or more to 22° or less with a horizontal plane.

3. An electronic device manufacturing apparatus according to claim 1, wherein
the substrate support plane of the shelf has a horizontal length of 3 mm or less.

4. An electronic device manufacturing apparatus according to claim 1, wherein
the position correcting mechanism sets the interval between the center point of the shelf and the center point of the substrate to 0.3 mm or less.

5. An electronic device manufacturing apparatus according to claim 1, wherein
the position correcting mechanism is provided inside a chamber in which the shelf is arranged.

6. An electronic device manufacturing apparatus according to claim 1, wherein
the position correcting mechanism is provided outside a chamber in which the shelf is arranged.

7. A method for manufacturing an electronic device using an electronic device manufacturing apparatus of claim 1, the method comprising the steps of:
placing the substrate on the shelf;
obtaining the position of the substrate placed on the shelf using the sensor; and
correcting the position of the substrate using the position correcting mechanism based on the position of the substrate obtained by the sensor.

8. An electronic device manufacturing apparatus comprising
a support which includes a shelf for supporting a substrate, wherein
the shelf includes a substrate support plane which forms an angle of 220 or more to less than 23° with a horizontal plane.

9. An electronic device manufacturing apparatus according to claim 8, wherein
the substrate support plane contacts a beveled face of the substrate.

10. An electronic device manufacturing apparatus according to claim 8, wherein
the interval between the center point of the shelf and the center point of the substrate placed on the shelf is 0.3 mm or less.

11. An electronic device manufacturing apparatus according to claim 8, wherein
the inner diameter of the shelf is larger than the diameter of a wafer as the substrate.

12. An electronic device manufacturing apparatus according to claim 8, wherein
the substrate support plane has a horizontal length of 2 mm or more.

13. An electronic device manufacturing apparatus comprising
a support which includes a shelf for supporting a substrate, wherein
the shelf includes a substrate support plane which forms an angle of 23° or more to less than 90° with a horizontal plane.

14. An electronic device manufacturing apparatus according to claim 13, wherein
the substrate support plane contacts an edge of the substrate at which a beveled face of the substrate meets an end face of the substrate.

15. An electronic device manufacturing apparatus according to claim 13, wherein
the interval between the center point of the shelf and the center point of the substrate placed on the shelf is 0.3 mm or less.

16. An electronic device manufacturing apparatus according to claim 13, wherein
the inner diameter of the shelf is larger than the diameter of the substrate.

17. An electronic device manufacturing apparatus according to claim 13, wherein
the substrate support plane has a horizontal length of 2 mm or more.

18. An electronic device manufacturing apparatus comprising:
a support which includes a shelf for supporting a substrate; wherein
the shelf includes a substrate support plane which forms an angle of 90° with a horizontal plane.

19. An electronic device manufacturing apparatus according to claim 18, wherein
the substrate support plane contacts an end face of the substrate.

20. An electronic device manufacturing apparatus according to claim 18, wherein
the interval between the center point of the shelf and the center point of the substrate placed on the shelf is 0.3 mm or less.

21. An electronic device manufacturing apparatus according to claim 18, wherein
the inner diameter of the shelf is the same as the diameter of the substrate.

22. An electronic device manufacturing apparatus according to claim 1 further comprising:
a heater which heats the substrate and is divided into two or more regions; and
a temperature measure which measures the temperature of the substrate, wherein
the substrate is subjected to thermal processing while the intensity of the heater is adjusted region by region in accordance with the temperature measured by the temperature measure.

23. An electronic device manufacturing apparatus according to claim 8 further comprising:
a heater which heats the substrate and is divided into two or more regions; and
a temperature measure which measures the temperature of the substrate, wherein
the substrate is subjected to thermal processing while the intensity of the heater is adjusted region by region in accordance with the temperature measured by the temperature measure.

24. An electronic device manufacturing apparatus according to claim 13 further comprising:
a heater which heats the substrate and is divided into two or more regions; and
a temperature measure which measures the temperature of the substrate, wherein
the substrate is subjected to thermal processing while the intensity of the heater is adjusted region by region in accordance with the temperature measured by the temperature measure.

25. An electronic device manufacturing apparatus according to claim 18 further comprising:
a heater which heats the substrate and is divided into two or more regions; and
a temperature measure which measures the temperature of the substrate, wherein
the substrate is subjected to thermal processing while the intensity of the heater is adjusted region by region in accordance with the temperature measured by the temperature measure.
